(19) United States
(12) Patent Application Publication
(10) Pub. No.: US 2020/0411647 A1
(43) Pub. Date: Dec. 31, 2020

(54) NITRIDE SEMICONDUCTOR DEVICE

(71) Applicant: FUJI ELECTRIC CO., LTD., Kawasaki-shi (JP)

(72) Inventors: Hideaki MATSUYAMA, Hino (JP); Katsunori UENO, Matsumoto (JP); Shinya TAKASHIMA, Hachioji (JP); Ryo TANAKA, Hino (JP); Yuta FUKUSHIMA, Hino (JP)

(73) Assignee: FUJI ELECTRIC CO., LTD., Kawasaki-shi (JP)

(21) Appl. No.: 16/895,692

(22) Filed: Jun. 8, 2020

(30) Foreign Application Priority Data
Jun. 28, 2019 (JP) 2019-121698
Mar. 10, 2020 (JP) 2020-041088

(51) Int. Cl. H01L 29/20; H01L 29/778; H01L 29/66

(52) U.S. Cl. CPC H01L 29/2003; H01L 29/66462; H01L 29/7786

(57) ABSTRACT

A nitride semiconductor device includes a transistor having a channel region in a gallium nitride-based semiconductor layer. The transistor includes: a gate insulating film provided above the gallium nitride-based semiconductor layer; an intermediate layer arranged between the gallium nitride-based semiconductor layer and the gate insulating film, having a band gap smaller than that of the gate insulating film, and having a band offset with the gallium nitride-based semiconductor layer; a gate electrode provided on the gate insulating film; a first conductivity type source region provided in the gallium nitride-based semiconductor layer; and a source electrode provided on the gallium nitride-based semiconductor layer and being in contact with the source region. The intermediate layer is arranged at a position opposed to the gate electrode through the gate insulating film and avoids a source contact region in which the source electrode is in contact with the source region.

### TECHNICAL FIELD

The present invention relates to a nitride semiconductor device.

### BACKGROUND ART

Conventionally, a vertical MOSFET using gallium nitride is known (for example, refer to PTL 1).

### CITATION LIST

### Patent Literature

PTL 1: JP 2017-188687 A

### SUMMARY OF INVENTION

### Technical Problem

A nitride semiconductor device capable of improving a mobility of a carrier in a channel region of a MOSFET is desired.

The present invention has been made in view of the above problem, and it is an object of the present invention to provide a nitride semiconductor device capable of improving a mobility of a carrier in a channel region.

### Solution to Problem

In order to solve the above problem, a nitride semiconductor device according to one mode of the present invention includes: a gallium nitride-based semiconductor substrate having a first main surface and a second main surface located on the opposite side of the first main surface; a gallium nitride-based semiconductor layer provided on the side of the first main surface of the gallium nitride-based semiconductor substrate; and a transistor having a channel region in the gallium nitride-based semiconductor layer. The transistor includes: a gate insulating film provided above the gallium nitride-based semiconductor layer; an intermediate layer arranged between the gallium nitride-based semiconductor layer and the gate insulating film, having a band gap smaller than that of the gate insulating film, and having a band offset with the gallium nitride-based semiconductor layer; a gate electrode provided on the gate insulating film; a first conductivity type source region provided in the gallium nitride-based semiconductor layer; and a source electrode provided on the gallium nitride-based semiconductor layer and being in contact with the source region. The intermediate layer is arranged at a position opposed to the gate electrode through the gate insulating film and avoids a source contact region in which the source electrode is in contact with the source region.

### Advantageous Effects of Invention

According to the present invention, a nitride semiconductor device capable of improving a mobility of a carrier in a channel region can be provided.

### BRIEF DESCRIPTION OF DRAWINGS

FIG. 1 is a plan view illustrating a configuration example of a gallium nitride semiconductor device according to a first embodiment of the present invention;

FIGS. 2A to 2E are cross-sectional views illustrating a manufacturing method of the gallium nitride semiconductor device according to the first embodiment of the present invention;

FIG. 3 is a graph illustrating a relation between a gate voltage Vg of a power MOSFET and an electron field-effect mobility p;

FIG. 4 is a diagram illustrating an energy band of a gate part of the gallium nitride semiconductor device according to the embodiment of the present invention;

FIG. 5 is a diagram illustrating bending of the energy band by a heterojunction of an AlN layer and a GaN layer;

FIG. 6 is a cross-sectional view illustrating a configuration example of a gallium nitride semiconductor device according to a second embodiment of the present invention;

FIGS. 7A to 7E are cross-sectional views illustrating a manufacturing method of the gallium nitride semiconductor device according to the second embodiment of the present invention;

FIG. 8 is a cross-sectional view illustrating a configuration example of a gallium nitride semiconductor device according to a third embodiment of the present invention;

FIGS. 9A to 9C are cross-sectional views illustrating a manufacturing method of the gallium nitride semiconductor device according to the third embodiment of the present invention;

FIG. 10 is a cross-sectional view illustrating a configuration example of a gallium nitride semiconductor device according to a fourth embodiment of the present invention; and

FIGS. 11A to 11C are cross-sectional views illustrating a manufacturing method of the gallium nitride semiconductor device according to the fourth embodiment of the present invention.

### DESCRIPTION OF EMBODIMENTS

Embodiments of the present invention will be described below. In the following description of the drawings, the same or similar portions are denoted by the same or similar reference numerals. However, it should be noted that the drawings are schematic and a relation between a thickness and a flat dimension, a ratio of thicknesses of respective devices or members, and the like are different from actual ones. Accordingly, specific thicknesses and dimensions should be determined with reference to the following description. In addition, it is certain that some portions have different dimensional relations and ratios between the drawings.

In the following description, a Z-axis positive direction is sometimes referred to as “up”, and a Z-axis negative direction is sometimes referred to as “down”. The terms “up” and “down” do not necessarily mean the vertical direction with respect to the ground. In other words, the directions of “up” and “down” are not limited to the direction of gravitational force. The terms “up” and “down” are merely convenient expressions for identifying relative positional relations in regions, layers, films, substrates, and the like and do not limit the technical idea of the present invention. It is certain that, when the plane of paper is rotated by 180 degrees, for example, “up” is changed to “down” and “down” is changed to “up”.

In the following description, the case where a first conductivity type is a N type and a second conductivity type is a P type is illustratively described. However, the relation between the conductivity types may be reversed such that the first conductivity type is a P type and the second conductivity type is a N type. In addition, “+” or “−” added to “P” or “N” means that a semiconductor region has an impurity concentration relatively higher or lower than that of a semiconductor region without “+” or “−”. However, it does not mean that, in semiconductor regions having the same P, the impurity concentrations of the semiconductor regions are strictly the same.

### First Embodiment

### (Configuration Example of GaN Semiconductor Device)

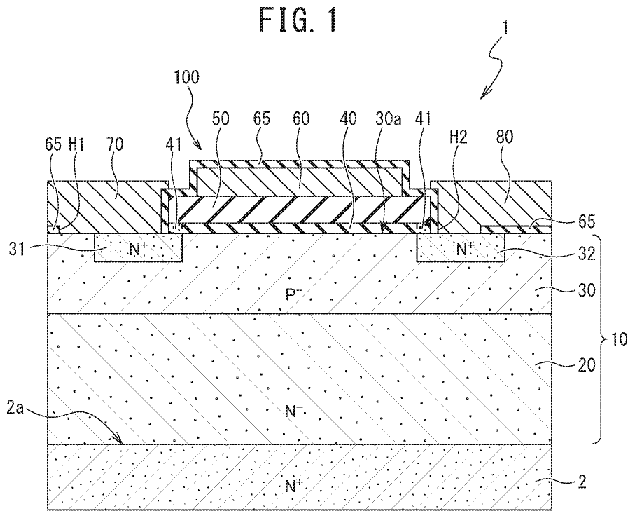

FIG. 1 is a plan view illustrating a configuration example of a gallium nitride semiconductor device (an example of a “nitride semiconductor device” of the present invention; hereinafter, GaN semiconductor device) 1 according to a first embodiment of the present invention. As illustrated in FIG. 1, the GaN semiconductor device 1 includes a gallium nitride substrate (an example of a “gallium nitride-based semiconductor substrate” of the present invention; hereinafter, GaN substrate) 2, a gallium nitride layer 10 (an example of a “gallium nitride-based semiconductor layer” of the present invention) provided on a surface 2a (an example of a “first main surface” of the present invention) of the GaN substrate 2, and a N type lateral MOSFET (Metal Oxide Semiconductor Field Effect Transistor) 100 having a channel region in the gallium nitride layer (hereinafter, GaN layer) 10. The lateral MOSFET 100 is an example of a “transistor” of the present invention.

The GaN layer 10 has a N⁻ type first gallium nitride layer (hereinafter, first GaN layer) 20 and a P⁻ type second gallium nitride layer (hereinafter, second GaN layer) 30 provided on the first GaN layer 20. In addition, the lateral MOSFET 100 includes an intermediate layer 40 provided on the second GaN layer 30, a gate insulating film 50 provided on the intermediate layer 40, a gate electrode 60 provided on the gate insulating film 50, and an insulating film 65 that covers the second GaN layer 30 and the gate electrode 60. The intermediate layer 40 is, for example, an aluminum nitride layer. The gate insulating film 50 is, for example, a silicon dioxide film (SiO₂ film).

In addition, the lateral MOSFET 100 includes a N⁺ type source region 31 provided in the second GaN layer 30, a N⁺ type drain region 32 provided in the second GaN layer 30, a source electrode 70 provided on the second GaN layer 30 and being in contact with the source region 31, and a drain electrode 80 provided on the second GaN layer 30 and being in contact with the drain region 32. The respective components configuring the GaN semiconductor device 1 will be described in detail below.

The GaN substrate 2 is, for example, a N⁺ type c-plane GaN single-crystalline substrate. A N type impurity contained in the GaN substrate 2 is one or more elements among Si (silicon), O (oxygen), and Ge (germanium). In one example, the N type impurity contained in the GaN substrate 2 is Si or O, and the impurity concentration of Si in the GaN substrate 2 is 5×10¹⁷ cm⁻³ or more.

The GaN substrate 2 may be a N type or a N⁻ type. The GaN substrate 2 may be a low-dislocation free-standing substrate having a dislocation density of less than 1×10⁷ cm⁻². When the GaN substrate 2 is the low-dislocation free-standing substrate, the dislocation density of the first GaN layer 20 formed on the GaN substrate 2 also becomes low. By using the low-dislocation substrate for the GaN substrate 2, even when a large-area power device is formed on the GaN substrate 2, a leakage current in the power device can be reduced. Accordingly, a manufacturing apparatus can manufacture the power device at a high yield rate. In addition, deep diffusion of an ion-implanted impurity along the dislocation in heat treatment can be prevented.

The first GaN layer 20 is provided on the surface of the GaN substrate 2. The first GaN layer 20 is, for example, a N⁻ type GaN single-crystalline layer and is a layer epitaxially grown on the surface 2a of the GaN substrate 2. The first GaN layer 20 is formed by doping of a N type impurity in the process of epitaxial growth. The N type impurity is, for example, Si. For example, the concentration of Si in the first GaN layer 20 is 2×10¹⁶ cm⁻³. The thickness of the first GaN layer 20 is 4 μm.

The second GaN layer 30 is provided on a surface of the first GaN layer 20. The second GaN layer 30 is, for example, a P⁻ type GaN single-crystalline layer and is a layer epitaxially grown on the surface of the first GaN layer 20. The second GaN layer 30 is formed by doping of a P type impurity in the process of epitaxial growth. Alternatively, the second GaN layer 30 may be formed by epitaxial growth of an intrinsic or a N type GaN layer, ion implantation of a P type impurity to a predetermined depth from the surface thereof, and heat treatment. For example, the concentration of Mg in the second GaN layer 30 is 1×10¹⁷ cm⁻³. The P type impurity is Mg (magnesium). In the second GaN layer 30, the concentration of Mg as the P type impurity is higher than the concentration of Si as a N type impurity. The thickness of the second GaN layer 30 is 1 μm.

The source region 31 and the drain region 32 are provided on a surface 30a of the second GaN layer 30 and in the vicinity thereof. The source region 31 and the drain region 32 are formed by ion implantation of a N type impurity to a predetermined depth from the surface 30a of the second GaN layer 30 and heat treatment. Each of the source region 31 and the drain region 32 has a N type impurity concentration (more properly speaking, a value obtained by subtracting the P type impurity concentration from the N type impurity concentration) higher than that of the first GaN layer 20. For example, the P type impurity is Mg, and the N type impurity is Si.

A channel of the lateral MOSFET 100 is formed in a region in the vicinity of the surface 30a of the second GaN layer 30, which is located between the source region 31 and the drain region 32 and is opposed to the gate electrode 60 through the gate insulating film 50. Hereinafter, the region in which the channel is formed is referred to as a channel region.

The intermediate layer 40 is provided on the surface 30a of the second GaN layer 30. The intermediate layer 40 is a wide-gap semiconductor layer having a band gap larger than that of the second GaN layer 30. The band gap means an energy level difference between a valence band and a conduction band in a band structure. The intermediate layer 40 is, for example, an ultrathin AlN single-crystalline layer and is a layer epitaxially grown on the surface 30a of the second GaN layer 30. The intermediate layer 40 forms a heterojunction with the surface 30a of the second GaN layer 30.

The case where an AlN layer is used as the intermediate layer 40 will be described. The lattice constants of AlN are c=0.4982 nm and a=0.3112 nm. The AlN layer is formed on the c-plane second GaN layer 30. The thickness of the AlN layer is in the c-axis direction. One molecule thickness of the AlN layer is c/2 and 0.25 nm. Therefore, the minimum thickness of the AlN layer is 0.25 nm. The thickness of the AlN layer is 0.25 nm or more and 7 nm or less, and more preferably, 0.25 nm or more and 2 nm or less. The reason why the maximum thickness of the AlN layer is 7 nm or less, and more preferably, 2 nm or less will be described below. In one example, the thickness of the AlN layer is 0.8 nm.

The intermediate layer 40 is not limited to the AlN layer and may be an aluminum nitride-based semiconductor layer other than the AlN layer. Examples of the aluminum nitride-based semiconductor layer other than the AlN layer include an aluminum gallium nitride layer (hereinafter, AlGaN layer), a laminated film in which the AlN layer is laminated on the AlGaN layer, and a laminated film in which the AlGaN layer is laminated on the AlN layer. The AlGaN layer is a nitride semiconductor layer in which Ga is added to the AlN layer. The AlGaN layer or the laminated film in which the AlGaN layer is laminated on the AlN layer is a wide-gap semiconductor layer having a band gap larger than that of the second GaN layer 30.

The intermediate layer 40 is not limited to the aluminum nitride-based semiconductor layer (the AlN layer, the AlGaN layer, and the like). The intermediate layer 40 may be composed of a material other than the aluminum nitride-based semiconductor layer, which has a band gap larger than that of the second GaN layer 30.

The gate insulating film 50 is provided on the intermediate layer 40. The gate insulating film 50 is, for example, a SiO₂ film (silicon dioxide film) or an Al₂O₃ film (aluminum oxide film). In one example, the gate insulating film 50 is the SiO₂ film, and the film thickness is 100 nm. The gate insulating film 50 is not limited to the SiO₂ film. The gate insulating film 50 should be composed of a material having a band gap larger than that of the intermediate layer 40.

An example of the material that can be used as the gate insulating film 50 or the intermediate layer 40, and the permittivity, the band gap, and the band offset with GaN thereof are illustrated in Table 1. The band offset means an energy level difference of conduction bands. As described above, the AlGaN layer can be used as the intermediate layer 40. The permittivity, the band gap, and the band offset with GaN of the AlGaN layer vary depending on the ratio between Al and Ga in the AlGaN layer, and approximate values are values between those of AlN and those of GaN illustrated in Table 1.

TABLE 1

| | | | Band Offset |
|---|---|---|---|
| | Permittivity | Band Gap | with GaN |
| Material | (Fm⁻¹) | (eV) | (eV) |
| SiO₂ | 3.9 | 9.0 | 3.4 |
| Al₂O₃ | 9.0 | 7.0 | 2.0 |
| AlN | 8.8 | 6.2 | 1.6 |
| C (diamond) | 5.5 | 5.5 | 1.3 |
| Si₃N₄ | 9.6 | 5.0 | 1.0 |
| Ga₂O₃ | 10.0 | 4.8 | 0.9 |
| GaN | 10.0 | 3.4 | 0.0 |

The gate insulating film 50 is composed of a material having a band gap larger than that of the intermediate layer 40. The intermediate layer 40 is composed of a material having a band gap larger than that of the second GaN layer 30 and having a band offset with the second GaN layer 30. A combination of the gate insulating film 50 with the intermediate layer 40 will be illustrated with reference to Table 1.

In the case where SiO₂ is used as the gate insulating film 50, as the intermediate layer 40, aluminum oxide (Al₂O₃), aluminum nitride (AlN), diamond, silicon nitride (Si₃N₄), or gallium oxide (Ga₂O₃) which has a band gap smaller than that of SiO₂ and has a band offset with GaN can be used.

In the case where Al₂O₃ is used as the gate insulating film 50, as the intermediate layer 40, AlN, diamond, Si₃N₄, or Ga₂O₃ which has a band gap smaller than that of Al₂O₃ and has a band offset with GaN can be used.

In the case where AlN is used as the gate insulating film 50, as the intermediate layer 40, diamond, Si₃N₄, or Ga₂O₃ which has a band gap smaller than that of AlN and has a band offset with GaN can be used.

In the case where diamond is used as the gate insulating film 50, as the intermediate layer 40, Si₃N₄ or Ga₂O₃ which has a band gap smaller than that of diamond and has a band offset with GaN can be used.

In the case where Si₃N₄ is used as the gate insulating film 50, as the intermediate layer 40, Ga₂O₃ which has a band gap smaller than that of Si₃N₄ and has a band offset with GaN can be used.

The gate electrode 60 is provided on the gate insulating film 50. The gate electrode 60 is adjacent to the channel region through the gate insulating film 50. The gate electrode 60 is composed of polysilicon doped with metal such as Al, Ti, Ni, or W, or an impurity.

The insulating film 65 is composed of, for example, a SiO₂ film. In the insulating film 65, a first contact hole H1 that opens the upper part of the source region 31 and the upper part of the second GaN layer 30, and a second contact hole H2 that opens the upper part of the drain region 32 are provided.

The source electrode 70 is provided on the insulating film 65. The source electrode 70 is in contact with the P⁻ type second GaN layer 30 and the N⁺ type source region 31 through the first contact hole H1 provided in the insulating film 65. In addition, the drain electrode 80 is provided on the insulating film 65. The drain electrode 80 is in contact with the N⁺ type drain region 32 through the second contact hole H2 provided in the insulating film 65. Accordingly, an on-state current of the lateral MOSFET 100 flows from the drain electrode 80 through the drain region 32, the channel region, and the source region 31 to the source electrode 70. In addition, the electric potential of the second GaN layer 30 is fixed to the electric potential of the source electrode 70.

The source electrode 70 and the drain electrode 80 are composed of Al, Al—Si alloy, Ni, Ni alloy, Ti—Al alloy, Ni—Au alloy, or the like. In addition, the source electrode 70 may have a barrier metal layer between the source electrode 70, and the second GaN layer 30 and the source region 31. The drain electrode 80 may have a barrier metal layer between the drain electrode 80 and the drain region 32. The barrier metal layers may be composed of Ti (titanium). In other words, each of the source electrode 70 and the drain electrode 80 may be a laminate of the Ti layer and the Al layer or a laminate of the Ti layer and the Al—Si alloy layer. The source electrode 70 may be an electrode doubling as a source pad which is not illustrated or may be an electrode provided separately from the source pad. The drain electrode 80 may be an electrode doubling as a drain pad which is not illustrated or may be an electrode provided separately from the drain pad.

### (Manufacturing Method of GaN Semiconductor Device)

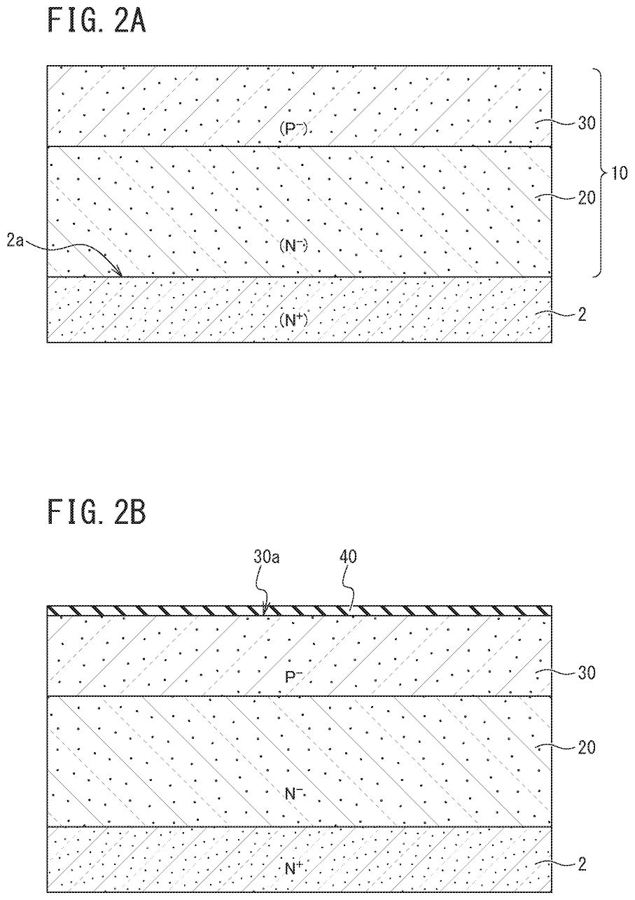

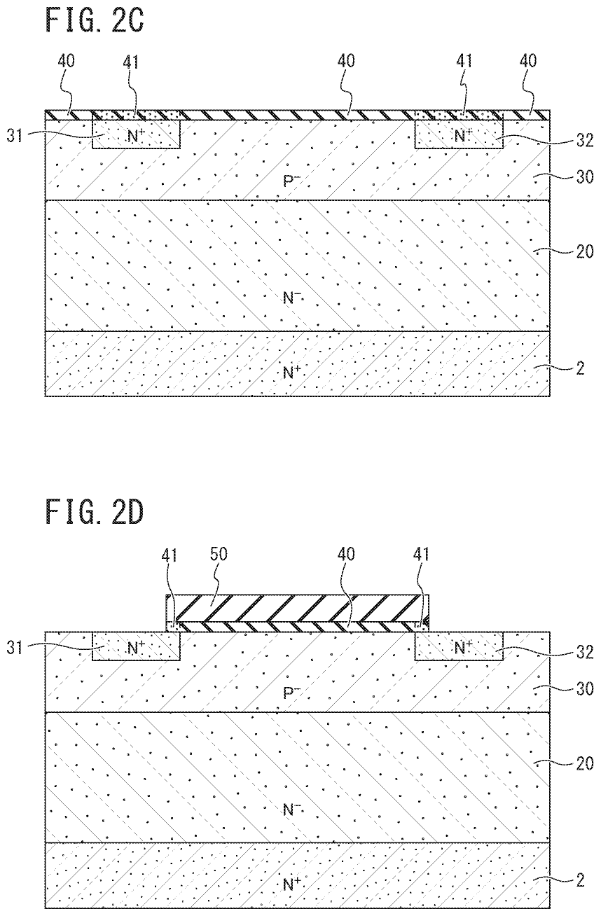

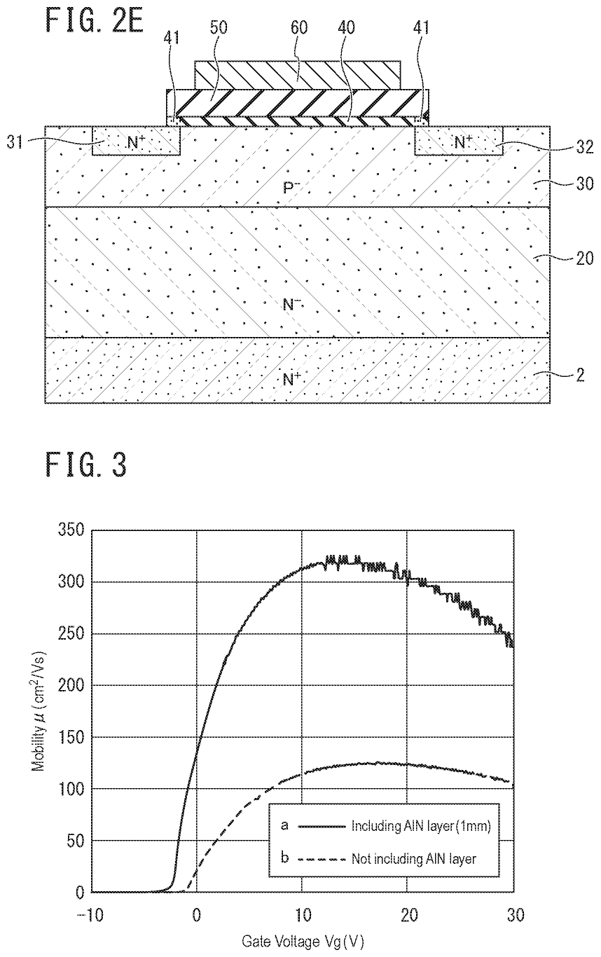

Next, a manufacturing method of the GaN semiconductor device 1 according to the first embodiment of the present invention will be described. FIGS. 2A to 2E are cross-sectional views illustrating the manufacturing method of the GaN semiconductor device 1 according to the first embodiment of the present invention in the order of steps. The GaN semiconductor device 1 is manufactured by various manufacturing apparatuses such as a deposition apparatus, an exposure apparatus, and an etching apparatus.

As illustrated in FIG. 2A, a manufacturing apparatus forms the first GaN layer 20 on the surface 2a of the GaN substrate 2. For example, the manufacturing apparatus epitaxially grows the first GaN layer 20 on the GaN substrate 2 by a metalorganic chemical vapor deposition method (MOCVD method). The manufacturing apparatus dopes the first GaN layer 20 with Si as a N type impurity in the process of epitaxially growing the first GaN layer 20. Next, the manufacturing apparatus epitaxially grows the second GaN layer 30 on the first GaN layer 20 by a MOCVD method. The manufacturing apparatus dopes the second GaN layer 30 with Mg as a P type impurity in the process of epitaxially growing the second GaN layer 30.

Next, as illustrated in FIG. 2B, the manufacturing apparatus epitaxially grows the intermediate layer 40 on the P⁻ type second GaN layer 30 by a MOCVD method. Next, the manufacturing apparatus performs heat treatment for a laminate of the GaN substrate 2, the first GaN layer 20, the second GaN layer 30, and the intermediate layer 40. The N type impurity such as Si introduced into the first GaN layer 20 and the P type impurity such as Mg introduced into the second GaN layer 30 are respectively activated by the heat treatment. The first GaN layer 20 becomes a N⁻ type, and the second GaN layer 30 becomes a P⁻ type.

Next, the manufacturing apparatus performs ion implantation of Si as a N type impurity in the second GaN layer 30 to regions in which the source and the drain are to be formed. For example, the manufacturing apparatus forms a mask (not illustrated) on the second GaN layer 30. The mask is composed of a SiO₂ film, an Al₂O₃ film, or a photoresist. The mask has a shape in which the upper parts of the regions in which the source and the drain are to be formed are opened and the upper part of the other region is covered. The manufacturing apparatus performs the ion implantation of Si to the second GaN layer 30 on which the mask is formed. After the ion implantation, the manufacturing apparatus removes the mask from the second GaN layer 30. As illustrated in FIG. 2C, parts of the intermediate layer 40, which are located above the regions in which the source and the drain are to be formed, are amorphized by the ion implantation to become amorphous intermediate layers 41.

Next, the manufacturing apparatus performs heat treatment for a laminate obtained by the ion implantation of Si to the regions in which the source and the drain are to be formed. The N type impurity such as Si introduced into the second GaN layer 30 is activated by the heat treatment, and the N⁺ type source region 31 and the N⁺ type drain region 32 are formed in the P⁻ type second GaN layer 30. In addition, in the source region 31 and the drain region 32, defects caused by the ion implantation can be recovered to some extent by the heat treatment.

Next, as illustrated in FIG. 2D, the manufacturing apparatus forms the gate insulating film 50 on the intermediate layers 40, 41 by a plasma CVD method. Next, the manufacturing apparatus partially wet etches the gate insulating film 50 and the intermediate layers 40, 41. Accordingly, the manufacturing apparatus leaves the gate insulating film 50 and the intermediate layers 40, 41 at a region that becomes a gate of the lateral MOSFET and removes the gate insulating film 50 and the intermediate layers 40, 41 from the other region.

Next, as illustrated in FIG. 2E, the manufacturing apparatus forms a metal film on the side of the surface 2a of the GaN substrate 2 and forms the gate electrode 60 by patterning the formed metal film. The forming of the metal film is performed by vapor deposition, sputtering, or the like. The patterning of the metal film is performed by dry etching or liftoff. Next, the manufacturing apparatus forms the insulating film 65 (refer to FIG. 1) by a plasma CVD method or the like. Next, the manufacturing apparatus partially etches the insulating film 65 to form the first contact hole H1 (refer to FIG. 1) and the second contact hole H2 (refer to FIG. 1). Next, the manufacturing apparatus forms the source electrode 70 (refer to FIG. 1) and the drain electrode 80 (refer to FIG. 1). The forming of the metal film is performed by vapor deposition, sputtering, or the like. The patterning of the metal film is performed by dry etching or liftoff. The GaN semiconductor device 1 illustrated in FIG. 1 is completed after the above steps.

### (Thickness of Intermediate Layer)

From the viewpoint of a threshold voltage, the viewpoint of prevention of parallel conduction, or the viewpoint of prevention of generation of 2D electron gas, the upper limit value of the thickness of the intermediate layer 40 is preferably 7 nm or less, and more preferably 2 nm or less. Each of the viewpoints will be described below.

### [Viewpoint of Threshold Voltage]

FIG. 3 is a result of an experiment conducted by the present inventor and is a graph illustrating a relation between a gate voltage Vg of a N type power MOSFET and an electron field-effect mobility p. The solid line a of FIG. 3 is data in the case where the thickness of the AlN layer as the intermediate layer 40 in the GaN semiconductor device 1 is 1 nm. The dashed line b of FIG. 3 is data in the case where the SiO₂ film as the gate insulating film 50 is indirect contact with the GaN layer without the AlN layer. In addition, the result of the experiment conducted by the present inventor is illustrated in Table 2. Table 2 illustrates a relation among the film thickness (nm) of the AlN layer, the maximum value μ_max (cm²/Vs) of the electron field-effect mobility μ, and the threshold voltage Vth of the power MOSFET. Table 2 illustrates data obtained when the thickness of the gate insulating film 50 is 100 nm.

TABLE 2

| Film Thickness (nm) | μ_max | Vth |
|---|---|---|
| of AlN Layer | (cm²/Vs) | (V) |
| 0 | 130 | 3.7 |
| 0.25 | 150 | 2.9 |
| 1 | 330 | 1.5 |
| 2 | 360 | 0.5 |

As illustrated in FIG. 3 and Table 2, in the case of without the AlN layer, the electron field-effect mobility p was 130 cm²/Vs and the threshold voltage Vth was 3.7 V. On the other hand, in the case where the AlN layer is 1 nm, the electron field-effect mobility p was 330 cm²/Vs and the threshold voltage Vth was 1.5 V. It was confirmed that, when the intermediate layer 40 is arranged between the gate insulating film 50 and the channel region as in the lateral MOSFET 100, the electron field-effect mobility p tends to become larger and the threshold voltage Vth tends to become smaller. This tendency is the same not only in the case where the intermediate layer 40 is the AlN layer but also in the case where the intermediate layer 40 is the AlGaN layer.

In the case where the intermediate layer 40 is the AlN layer (or the AlGaN layer) and the base of the intermediate layer 40 is the GaN layer, stress-generated piezoelectric polarization is generated at an interface between the intermediate layer 40 and the GaN layer. In the intermediate layer 40, as the Al concentration increases (more specifically, as the composition approaches AlN), the stress becomes larger and the piezoelectric polarization becomes larger. In addition, in the case where the piezoelectric polarization is generated, as the thickness of the intermediate layer 40 becomes thicker, a polarization distance between a surface (nearer the gate electrode) and a rear surface (nearer GaN) becomes larger. As the polarization distance becomes larger, the impact of a polarization charge at the interface between the intermediate layer 40 and the GaN layer becomes stronger, and the threshold voltage Vth tends to become smaller.

In the case where the AlN layer (or the AlGaN layer) is not used for the intermediate layer 40, the piezoelectric polarization is not generated, or even if the piezoelectric polarization is generated, the impact thereof is small. Therefore, as the thickness of the intermediate layer 40 becomes thicker, the threshold voltage Vth tends to increase.

When the lateral MOSFET 100 is used as a normally-off MOSFET, the threshold voltage Vth needs to be positive and is preferably 0.5 V or more. From this viewpoint, in the case where the AlN layer (or the AlGaN layer) is used for the intermediate layer 40, the film thickness thereof is preferably 2 nm or less.

In addition, when the lateral MOSFET 100 is used as a normally-off power MOSFET, the threshold voltage Vth needs to be positive and is preferably 3.0 V or more. The threshold voltage Vth 3.0 V can be achieved by investigating a relation between the film thickness of the gate insulating film 50 and the threshold voltage Vth in advance and determining the film thickness of the gate insulating film 50 such that the threshold voltage Vth is 3.0 V or more.

In order to achieve the threshold voltage Vth 3.0 V, a film other than the AlN layer (or the AlGaN layer) may be used for the intermediate layer 40. Accordingly, not only the film thickness of the gate insulating film 50 but also the film thickness of the intermediate layer 40 is made thick, so that the threshold voltage Vth can be increased. Examples of the film other than the AlN layer (or the AlGaN layer) include aluminum oxide (Al₂O₃), diamond, silicon nitride (Si₃N₄), and gallium oxide (Ga₂O₃) illustrated in Table 1.

The threshold voltage Vth is calculated by, for example, the following equations.

Vth=Qs/C+2□s

Qs=q×Na×W

W=√(4×ε×k×T×ln(Na/ni/q^{2Na}))

In the above respective equations, Qs represents the charge amount in a depletion layer formed on the GaN surface, C represents an electrical capacitance of the whole of the insulating film, □s represents a surface potential of GaN, q represents an elementary charge, Na represents an acceptor concentration of GaN, W represents a width of the depletion layer formed on the GaN surface, ε represents a permittivity of GaN, k represents the Boltzmann coefficient, T represents an absolute temperature, and ni represents an intrinsic carrier concentration of GaN. In the lateral MOSFET 100 illustrated in FIG. 1, the second GaN layer 30 corresponds to GaN described above.

### [Viewpoint of Prevention of Parallel Conduction]

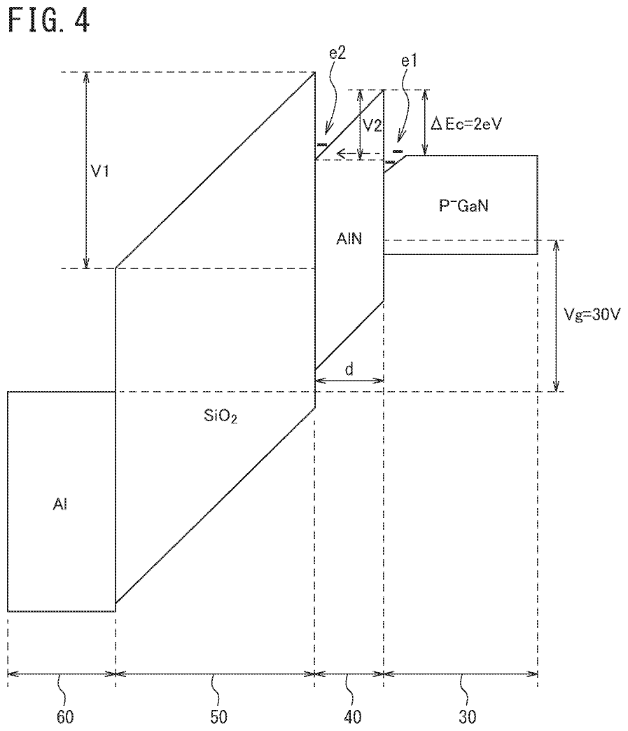

FIG. 4 is a diagram illustrating an energy band of a gate part of the lateral MOSFET 100 according to the embodiment of the present invention. FIG. 4 illustrates a state where the gate voltage Vg is applied to the gate electrode 60. From the viewpoint of prevention of parallel conduction, the thickness d of the intermediate layer 40 is preferably 7 nm or less.

Initially, parallel conduction will be described. When the gate voltage Vg is applied to the gate electrode 60, as illustrated in FIG. 4, a voltage V1 is applied to the gate insulating film 50 to incline a conduction band of the gate insulating film 50, a voltage V2 is applied to the intermediate layer 40 to incline a conduction band of the intermediate layer 40, and a part of electrons e1 existing in the channel region (refer to FIG. 1) tunnels to the conduction band of the intermediate layer 40 as indicated by the dashed arrow. The voltage V1 corresponds to the amount of voltage drop in the gate insulating film 50, and the voltage V2 corresponds to the amount of voltage drop in the intermediate layer 40. For example, V1>V2.

Electrons e2 tunneled to the conduction band of the intermediate layer 40 conduct between the source and the drain along an interface between the gate insulating film 50 and the intermediate layer 40. In other words, as a conduction path between the source and the drain, a path passing through the interface between the gate insulating film 50 and the intermediate layer 40 is generated in addition to a path passing through the channel region. This phenomenon is parallel conduction. Electrons in the channel region are decreased by the parallel conduction, and therefore, a mobility of the electrons in the channel region is decreased. In order to further suppress the decrease in the mobility, prevention of the parallel conduction is effective.

Next, an example of parameters of the respective layers configuring the gate part of the lateral MOSFET 100 will be described. The P⁻ type second GaN layer 30 has a band gap of 3.4 eV and a relative permittivity of 9. The gate insulating film 50 is a SiO₂ film, and the thickness thereof is 100 nm. The SiO₂ film has a band gap of 9.1 eV and a relative permittivity of 3.9. When the maximum value of the gate voltage Vg is set to be 30 V, an electric field E in the gate insulating film 50 is 3 MV/cm at a maximum. The intermediate layer 40 is an AlN layer. A difference between an energy level of the conduction band of the AlN layer and an energy level of a conduction band of the second GaN layer 30 (band offset) ΔE2 is 2 eV.

In order to prevent tunneling from the conduction band of the second GaN layer 30 to the conduction band of the intermediate layer 40, in strong inversion, an electric potential difference V2 (=E×d) in the intermediate layer 40 should be smaller than the band offset ΔE2 (V2<ΔE2). The strong inversion means Qg≥1×10¹³ [cm⁻²]×q. Qg represents the total value of a charge accumulated in the gate part, and q represents an elementary charge.

When satisfying “Qg≥1×10¹³ cm⁻²×q and V2<ΔE2”, even if an inversion layer (the channel region) of the lateral MOSFET 100 is strong inverted and a sufficiently large current flows, a charge can be prevented from being stored at the interface between the gate insulating film 50 and the intermediate layer 40.

Since q=1.602×10⁻¹⁹ [C], Qg≥(1×10¹³)×(1.602×10⁻¹⁹)=1.602×10⁻⁶.

In addition, when an electrical capacitance of the intermediate layer 40 is C2, V2=Qg/C2. Therefore, the determination “Qg≥1×10¹³ cm⁻²×q and V2<ΔE2” can also be represented by “1.602×10⁻⁶/C2<ΔE2”.

“1.602×10⁻⁶/C2<ΔE2” is a condition that electrons are not accumulated at the interface between the gate insulating film 50 and the intermediate layer 40 even when a voltage is sufficiently applied to the gate electrode and a charge is sufficiently accumulated at an interface between the intermediate layer 40 and the second GaN layer 30. “1.602×10⁻⁶/C2<ΔE2” may be represented by “1.60×10⁻⁶/C2<ΔE2” obtained by rounding off “1.602×10⁻⁶/C2<ΔE2” to two decimal places or may be represented by “1.6×10⁻⁶/C2<ΔE2” obtained by rounding off “1.602×10⁻⁶/C2<ΔE2” to one decimal place.

The above condition for preventing tunneling may be determined by the film thickness of the intermediate layer. More specifically, the band offset ΔE2, the electric field E in the intermediate layer 40, and the thickness d of the intermediate layer 40 may satisfy the following equation (1).

D<ΔE2/E (1)

By plugging E=3 MV/cm and ΔE2=2 eV in the equation (1), approximately d<7 nm is obtained. Therefore, from the viewpoint of prevention of parallel conduction, the film thickness of the intermediate layer 40 is preferably 7 nm or less. When using the AlGaN layer or the laminated film of the Al layer and the AlGaN layer as the intermediate layer 40, the film thickness is preferably 7 nm or less similarly to the above.

### [Viewpoint of Prevention of Generation of 2D Electron Gas]

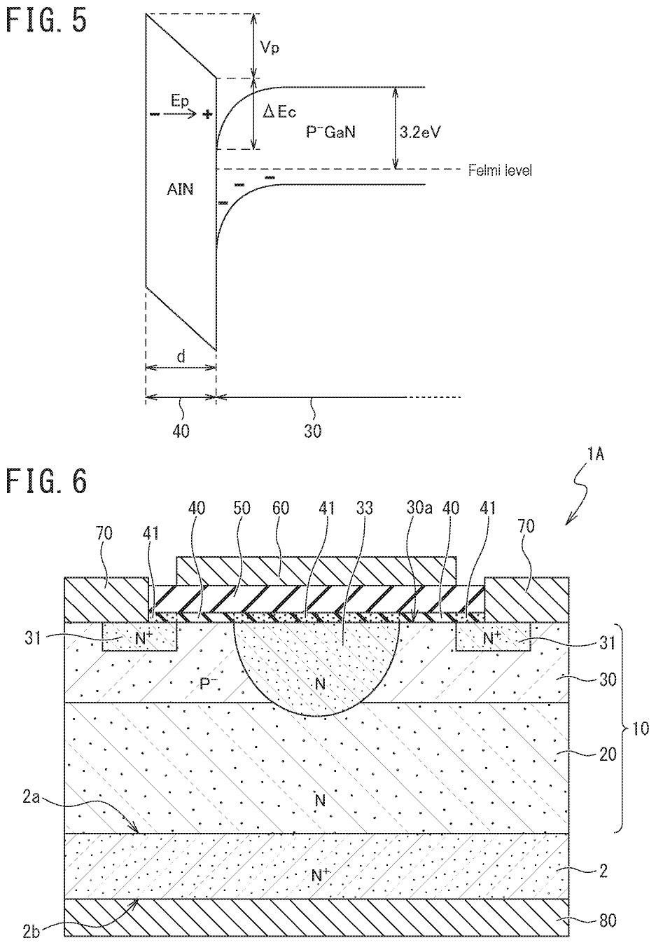

FIG. 5 is a diagram illustrating bending of the energy band by a heterojunction of the intermediate layer 40 and the second GaN layer 30. The intermediate layer 40 is an AlN layer. The intermediate layer 40 and the P⁻ type second GaN layer 30 form a heterojunction, so that polarization (spontaneous polarization and piezoelectric polarization) occurs in the intermediate layer 40. The polarization generates an internal electric field Ep in the intermediate layer 40 and an internal voltage Vp in the intermediate layer 40. For example, an interface polarization charge Nc generated in the intermediate layer 40 by the above heterojunction is 6E13 cm⁻² at a maximum, and the internal electric field Ep is 2.2 V/cm at a maximum. When using Al_{0.3}Ga_{0.7}N instead of the AlN layer as the intermediate layer 40, the interface polarization charge Nc generated by the above heterojunction is 1.5E13 cm⁻² at a maximum, and the internal electric field Ep is 0.55 V/cm at a maximum. The internal voltage Vp in the intermediate layer 40, the internal electric field Ep in the intermediate layer 40, and the thickness d of the intermediate layer 40 satisfy the following equation (2).

Vp=Ep×d (2)

In addition, in the second GaN layer 30 in contact with the intermediate layer 40, the energy band bends by the internal voltage Vp, and a charge corresponding to the above interface polarization charge is generated. When the energy band of the second GaN layer 30 bends and the conduction band reaches the Fermi level, 2d electron gas (2DEG) is generated. When the 2DEG is generated, the channel is easy to be in an on-state (normally-on). In order to make the characteristics of the MOSFET normally-off, it is preferable to prevent generation of 2DEG.

A difference between the level of the conduction band of the second GaN layer 30 and the Fermi level is 3.2 eV. In order to prevent generation of 2DEG, a voltage to be applied to the second GaN layer 30 (i.e., the internal voltage Vp in the intermediate layer 40) should be smaller than 3.2 eV, and the following equation (3) should be satisfied.

Vp<3.2 eV (3)

The equation (3) can be represented as the equation (3)′ by the equation (2).

Vp=(Ep×d)<3.2 eV (3)′

By plugging the internal electric field Ep=2.2 V/cm of the intermediate layer 40 in the equation (3)′, approximately d<1.5 nm is obtained. In addition, by plugging the internal electric field Ep=0.55 V/cm of Al_{0.3}Ga_{0.7}N in the equation (3)′, approximately d<6 nm is obtained.

From the viewpoint of prevention of generation of 2DEG, the thickness of the intermediate layer 40 is preferably 2 nm or less depending on a composition such as the presence or absence of Ga. When using the AlGaN layer or the laminated film of the Al layer and the AlGaN layer as the intermediate layer 40, the film thickness is preferably 2 nm or less similarly to the above.

As described above, the GaN semiconductor device 1 according to the first embodiment of the present invention includes the GaN substrate 2 having the surface 2a and a rear surface 2b located on the opposite side of the surface 2a, the P⁻ type second GaN layer 30 provided on the side of the surface 2a of the GaN substrate 2, and the lateral MOSFET 100 having the channel region in the second GaN layer 30. The lateral MOSFET 100 has the gate insulating film 50 provided above the second GaN layer 30, the intermediate layer 40 arranged between the second GaN layer 30 and the gate insulating film 50, the gate electrode 60 provided on the gate insulating film 50, the N⁺ type source region 31 provided in the second GaN layer 30, and the source electrode 70 provided on the second GaN layer 30 and being in contact with the source region 31.

The intermediate layer 40 has a band gap smaller than that of the gate insulating film 50 and has a band offset with the second GaN layer 30. The intermediate layer 40 is arranged at a position opposed to the gate electrode 60 through the gate insulating film 50 (for example, below the gate electrode 60). The intermediate layer 40 has high resistance and inhibits ohmic contact, and thus, avoids a source contact region SC in which the source electrode 70 is in contact with the source region 31. More specifically, the intermediate layer 40 avoids a position above the source contact region SC and a position below the source contact region SC. In addition, the intermediate layer 40 avoids not only the source contact region SC but also a drain contact region DC in which the drain electrode 80 is in contact with the drain region 32. More specifically, the intermediate layer 40 avoids a position above the drain contact region DC and a position below the drain contact region DC.

For example, when viewed in a plan view from a normal direction of the surface 30a of the second GaN layer 30, the intermediate layer 40 avoids the source contact region SC and the drain contact region DC, respectively. The intermediate layer 40 is not arranged above the source contact region SC, below the source contact region SC, and between the source electrode 70 and the source region 31 (i.e., the source contact region SC). In addition, the intermediate layer 40 is not arranged above the drain contact region DC, below the drain contact region DC, and between the drain electrode 80 and the drain region 32 (i.e., the drain contact region DC).

In other words, the source electrode 70 is in direct contact with the source region 31. In addition, the drain electrode 80 is in direct contact with the drain region 32. The intermediate layer 40 is arranged between the source electrode 70 and the drain electrode 80. Alternatively, the intermediate layer 40 is arranged between the source contact region SC and the drain contact region DC.

Accordingly, the channel region of the lateral MOSFET is covered with the intermediate layer 40 having a band gap larger than that of the second GaN layer 30. The intermediate layer 40 preferably forms a heterojunction with the second GaN layer 30. For example, the intermediate layer 40 is directly provided on the second GaN layer 30. The crystal structure of the base second GaN layer 30 is a single crystal, and the crystal structure of the intermediate layer 40 is also a single crystal similarly to the base GaN layer. The lattice constants of both the intermediate layer 40 and the second GaN layer 30 are the same or approximately the same in the vicinity of an interface between the intermediate layer 40 and the second GaN layer 30. Accordingly, the intermediate layer 40 can suppress electron scattering in the vicinity of the interface with the second GaN layer 30, and a mean free path of electrons in the channel region can be lengthened. Accordingly, in the channel region, the mobility of electrons can be further improved.

When the electrical capacitance of the intermediate layer 40 is C2 and the band offset between the intermediate layer 40 and the second GaN layer 30 is ΔE2, the relation of 1.6×10⁻⁶/C2<ΔE2 is preferably satisfied. Accordingly, electrons existing in the channel region of the lateral MOSFET 100 can be prevented from tunneling to the conduction band of the intermediate layer 40, and parallel conduction can be prevented. Accordingly, in the channel region, a decrease in electrons can be suppressed, and therefore, the mobility of electrons can be further improved.

The thickness of the intermediate layer 40 is preferably 0.25 nm or more and 7 nm or less. Accordingly, electrons existing in the channel region can be prevented from tunneling to the conduction band of the intermediate layer 40, and parallel conduction can be prevented. Accordingly, in the channel region, a decrease in electrons can be suppressed, and therefore, the mobility of electrons can be further improved.

The thickness of the intermediate layer 40 is more preferably 0.25 nm or more and 2 nm or less. Accordingly, generation of 2DEG can be suppressed, and the threshold voltage Vth can be set to be 0.5 V or more. Accordingly, the characteristics of the MOSFET can be prevented from being normally-on.

In addition, the threshold voltage Vh of the lateral MOSFET 100 may be set to be 3.0 V or more. Accordingly, the lateral MOSFET 100 can be used as a power MOSFET. The threshold voltage Vth may be adjusted to be an arbitrary value of 3.0 V or more by thickening the thickness of the gate insulating film 50. In addition, when the film other than the AlN layer (or the AlGaN layer) is used for the intermediate layer 40, the impact of the piezoelectric polarization can be ignored, and therefore, the threshold voltage Vth may be increased by thickening the film thickness of the intermediate layer 40.

### Second Embodiment

In the above first embodiment, the case where the nitride semiconductor device according to the embodiment of the present invention is a lateral power MOSFET has been described. However, the present invention is not limited thereto. The nitride semiconductor device according to the embodiment of the present invention may be a vertical power MOSFET.

FIG. 6 is a cross-sectional view illustrating a configuration example of a GaN semiconductor device 1A according to a second embodiment of the present invention. As illustrated in FIG. 6, the GaN semiconductor device 1A includes the GaN substrate 2, the N⁻ type first GaN layer 20 provided on the GaN substrate 2, the P⁻ type second GaN layer 30 provided on the first GaN layer 20, and a N type vertical MOSFET 100A having a channel region in the second GaN layer 30. The vertical MOSFET 100A is an example of the “transistor” of the present invention. The vertical MOSFET 100A includes the intermediate layer 40 provided on the second GaN layer 30, the gate insulating film 50 provided on the intermediate layer 40, and the gate electrode 60 provided on the gate insulating film 50.

In addition, the vertical MOSFET 100A includes the N⁺ type source region 31 provided in the second GaN layer 30, the source electrode 70 in contact with the source region 31, and the drain electrode 80. The drain electrode 80 is provided on the side of the rear surface 2b (an example of a “second main surface” of the present invention) located on the opposite side of the surface 2a of the GaN substrate 2.

In addition, the vertical MOSFET 100A includes a N type impurity region 33 provided in the second GaN layer 30. The impurity region 33 contains a N type impurity such as Si or O. In the impurity region 33, the concentration of the N type impurity such as Si is higher than the concentration of the P type impurity such as Mg. The impurity region 33 is deeply formed in the thickness direction of the second GaN layer 30 from the surface 30a of the second GaN layer 30 and reaches the first GaN layer 20. In addition, in the horizontal direction perpendicular to the thickness direction of the second GaN layer 30, the impurity region 33 is separately arranged at a certain distance from the source region 31.

In the GaN semiconductor device 1A, a region in the vicinity of the surface 30a of the second GaN layer 30, which is located between the impurity region 33 and the source region 31 and is opposed to the gate electrode 60 through the gate insulating film 50, becomes the channel region of the vertical MOSFET 100A. An on-state current of the vertical MOSFET 100A flows from the drain electrode 80 through the GaN substrate 2, the first GaN layer 20, the impurity region 33, the channel region, and the source region 31 to the source electrode 70. In addition, the source electrode 70 is in contact with not only the source region 31 but also the surface 30a of the second GaN layer 30. Accordingly, the electric potential of the second GaN layer 30 is fixed to the electric potential of the source electrode 70.

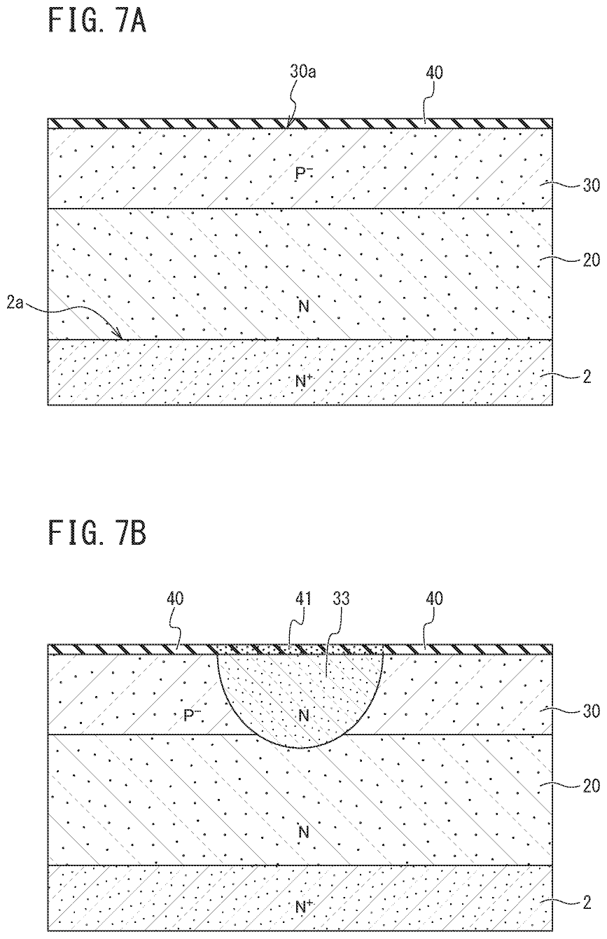

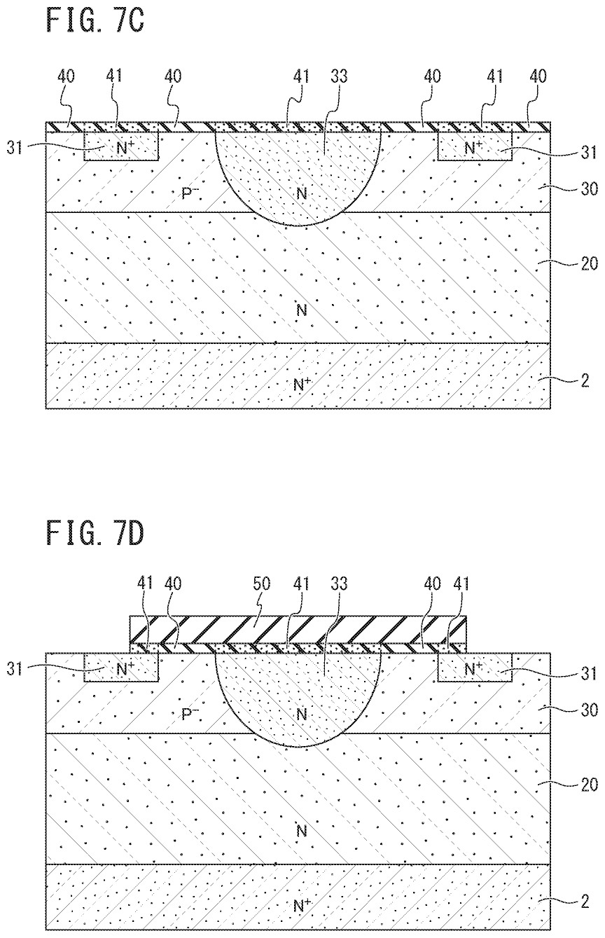

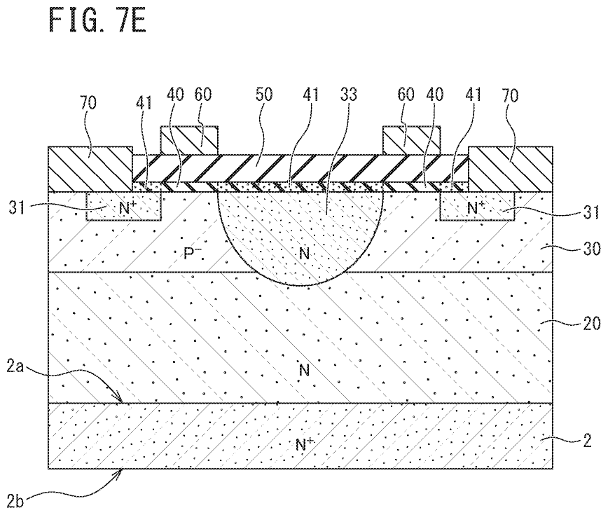

FIGS. 7A to 7E are cross-sectional views illustrating a manufacturing method of the GaN semiconductor device 1A according to the second embodiment of the present invention in the order of steps. The GaN semiconductor device 1A is manufactured by various manufacturing apparatuses such as a deposition apparatus, an exposure apparatus, and an etching apparatus. In FIG. 7A, the steps are the same as those in the first embodiment until the step of epitaxially growing the intermediate layer 40 on the P⁻ type second GaN layer 30. After forming the intermediate layer 40, the manufacturing apparatus performs ion implantation of Si as a N type impurity in the second GaN layer 30 to a region in which the impurity region 33 is to be formed. As illustrated in FIG. 7B, a part of the single-crystalline intermediate layer 40, which is located above the region in which the impurity region 33 is to be formed, is amorphized by the ion implantation to become an amorphous intermediate layer 41.

Next, the manufacturing apparatus performs heat treatment (hereinafter, first heat treatment) for a laminate obtained by the ion implantation of Si to the region in which the impurity region 33 is to be formed. The N type impurity such as Si introduced into the second GaN layer 30 is activated by the first heat treatment, and the N type impurity region 33 is formed in the P⁻ type second GaN layer 30. In addition, in the impurity region 33, defects caused by the ion implantation can be recovered to some extent by the first heat treatment.

Next, the manufacturing apparatus performs ion implantation of Si as a N type impurity in the second GaN layer 30 to a region in which the source is to be formed. As illustrated in FIG. 7C, a part of the single-crystalline intermediate layer 40, which is located above the region in which the source is to be formed, is amorphized by the ion implantation to become an amorphous intermediate layer 41.

Next, the manufacturing apparatus performs second heat treatment for a laminate obtained by the ion implantation of Si to the region in which the source is to be formed. The N type impurity such as Si introduced into the second GaN layer 30 is activated by the second heat treatment, and the N⁺ type source region 31 is formed in the P⁻ type second GaN layer 30. In addition, in the source region 31, defects caused by the ion implantation can be recovered to some extent by the second heat treatment.

In the embodiment of the present invention, the second heat treatment may be performed without performing the first heat treatment. In this case, the N type impurity region 33 and the N⁺ type source region 31 are formed by the second heat treatment.

Next, as illustrated in FIG. 7D, the manufacturing apparatus forms the gate insulating film 50 on the intermediate layers 40, 41 by a plasma CVD method. Next, the manufacturing apparatus partially wet etches the gate insulating film 50 and the intermediate layers 40, 41 to expose the surface of the source region 31.

Next, as illustrated in FIG. 7E, the manufacturing apparatus forms a metal film on the side of the surface 2a of the GaN substrate 2 and forms the gate electrode 60 and the source electrode 70 by patterning the formed metal film. The forming of the metal film is performed by vapor deposition, sputtering, or the like. The patterning of the metal film is performed by dry etching or liftoff.

In addition, before or after the forming step of the gate electrode 60 and the source electrode 70, the manufacturing apparatus forms a metal film on the side of the rear surface 2b of the GaN substrate 2 and forms the drain electrode 80 (refer to FIG. 6) by patterning the formed metal film if necessary. The forming of the metal film is performed by vapor deposition, sputtering, or the like. The patterning of the metal film is performed by dry etching or liftoff. The GaN semiconductor device 1A illustrated in FIG. 6 is completed after the above steps.

As described above, the GaN semiconductor device 1A according to the second embodiment includes the vertical MOSFET 100A having the channel region in the second GaN layer 30. The vertical MOSFET 100A has the intermediate layer 40 arranged between the second GaN layer 30 and the gate insulating film 50. The intermediate layer 40 has a band gap smaller than that of the gate insulating film 50 and has a band offset with the second GaN layer 30. The intermediate layer 40 is arranged at a position opposed to the gate electrode 60 through the gate insulating film 50. The intermediate layer 40 has high resistance and inhibits ohmic contact, and thus, avoids the source contact region SC in which the source electrode 70 is in contact with the source region 31.

Accordingly, the channel region of the vertical MOSFET is covered with the intermediate layer 40 having a band gap larger than that of the second GaN layer 30. The intermediate layer 40 preferably forms a heterojunction with the second GaN layer 30 also in the GaN semiconductor device 1A. Accordingly, the intermediate layer 40 can suppress electron scattering in the vicinity of the interface with the second GaN layer 30, and a mean free path of electrons in the channel region can be lengthened. Accordingly, in the channel region, the mobility of electrons can be further improved.

When the electrical capacitance of the intermediate layer 40 is C2 and the band offset between the intermediate layer 40 and the second GaN layer 30 is ΔE2, the relation of 1.6×10⁻⁶/C2<ΔE2 is preferably satisfied also in the GaN semiconductor device 1A. Accordingly, electrons existing in the channel region of the vertical MOSFET 100A can be prevented from tunneling to the conduction band of the intermediate layer 40, and parallel conduction can be prevented. Accordingly, in the channel region, a decrease in electrons can be suppressed, and therefore, the mobility of electrons can be further improved.

The thickness of the intermediate layer 40 is preferably 0.25 nm or more and 7 nm or less also in the GaN semiconductor device 1A. Accordingly, parallel conduction can be prevented, and therefore, the mobility of electrons in the channel region can be further improved. In addition, the thickness of the intermediate layer 40 is more preferably 0.25 nm or more and 2 nm or less. Accordingly, generation of 2DEG can be suppressed, and the threshold voltage Vth can be set to be 0.5 V or more. The characteristics of the vertical MOSFET can be prevented from being normally-on.

In addition, the threshold voltage of the vertical MOSFET 100A may be set to be 3.0 V or more. Accordingly, the vertical MOSFET 100A can be used as a power MOSFET.

### Third Embodiment

In the above second embodiment, the case where the channel region is formed in the P type second GaN layer 30 has been described. However, the present invention is not limited thereto. The channel region may be formed not in the P type second GaN layer 30 but in a P type well region.

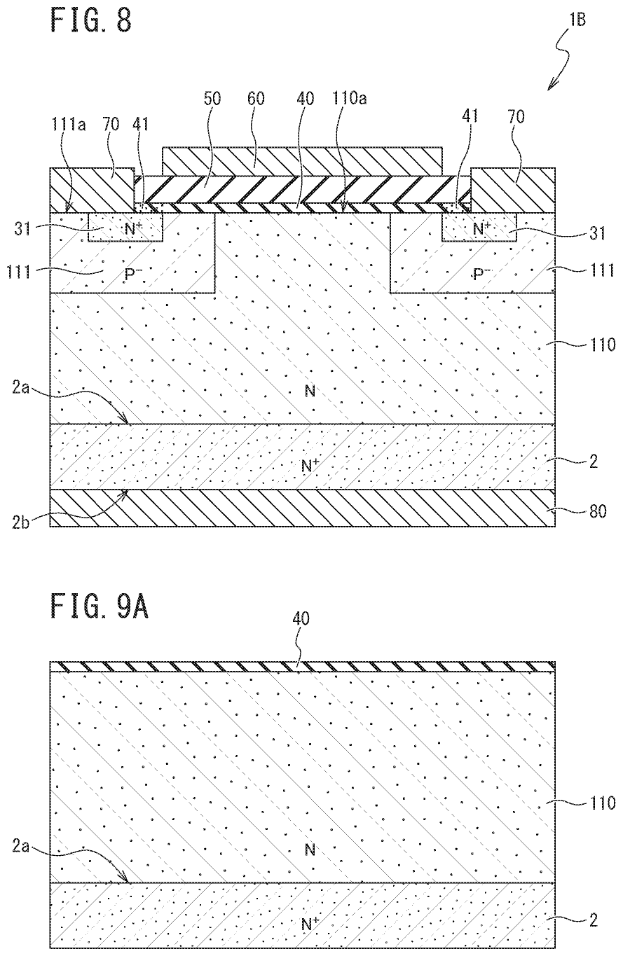

FIG. 8 is a cross-sectional view illustrating a configuration example of a GaN semiconductor device 1B according to a third embodiment of the present invention. As illustrated in FIG. 8, the GaN semiconductor device 1B includes the GaN substrate 2, a N⁻ type GaN layer 110 provided on the GaN substrate 2, a P⁻ type well region 111 provided in the GaN layer 110, and a N type vertical MOSFET 100B having a channel region in the well region 111.

The vertical MOSFET 100B is an example of the “transistor” of the present invention. The vertical MOSFET 100B includes the intermediate layer 40 provided on the GaN layer 110, the gate insulating film 50 provided on the intermediate layer 40, and the gate electrode 60 provided on the gate insulating film 50. In addition, the vertical MOSFET 100B includes the N⁺ type source region 31 provided on the inside of the well region 111, the source electrode 70 provided on the GaN layer 110 and being in contact with the source region 31, and the drain electrode 80 provided on the side of the rear surface 2b of the GaN substrate 2.

In the GaN semiconductor device 1B, a region in the vicinity of a surface 111a of the well region 111, which is located between the GaN layer 110 and the source region 31 and is opposed to the gate electrode 60 through the gate insulating film 50, becomes the channel region of the vertical MOSFET 100B. An on-state current of the vertical MOSFET 100B flows from the drain electrode 80 through the GaN substrate 2, the GaN layer 110, the channel region, and the source region 31 to the source electrode 70. In addition, the source electrode 70 is in contact with not only the source region 31 but also the surface 111a of the well region 111. Accordingly, the electric potential of the well region 111 is fixed to the electric potential of the source electrode 70.

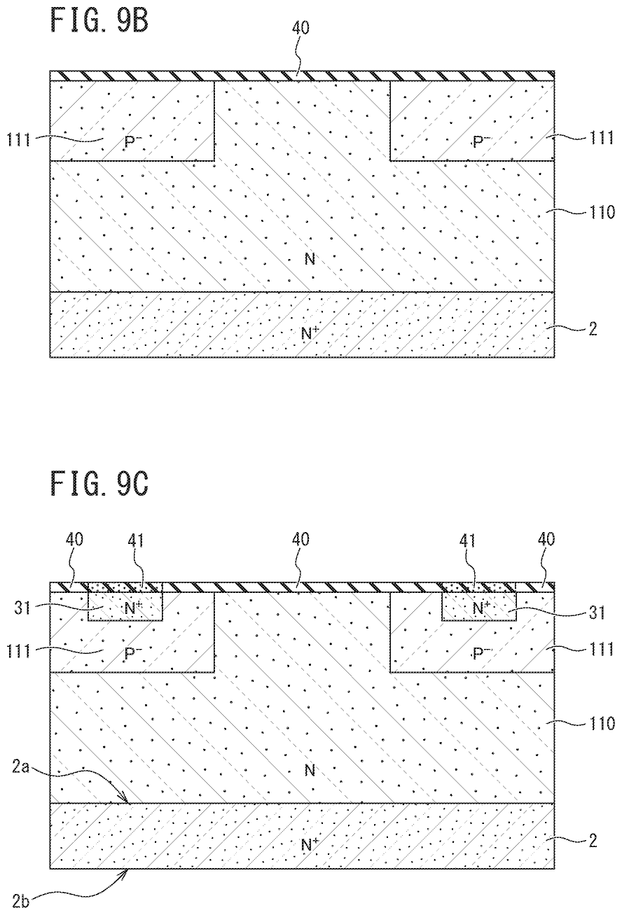

FIGS. 9A to 9C are cross-sectional views illustrating a manufacturing method of the GaN semiconductor device 1B according to the third embodiment of the present invention in the order of steps. The GaN semiconductor device 1B is manufactured by various manufacturing apparatuses such as a deposition apparatus, an exposure apparatus, and an etching apparatus. As illustrated in FIG. 9A, the manufacturing apparatus forms the GaN layer 110 on the surface 2a of the GaN substrate 2. For example, the manufacturing apparatus epitaxially grows the GaN layer 110 on the surface 2a of the GaN substrate 2 by a MOCVD method. The manufacturing apparatus dopes the GaN layer 110 with Si as a N type impurity in the process of epitaxially growing the GaN layer 110. The manufacturing apparatus epitaxially grows the intermediate layer 40 on a surface of the GaN layer 110 by a MOCVD method.

Next, as illustrated in FIG. 9B, the manufacturing apparatus performs ion implantation of Mg as a P type impurity in the GaN layer 110 to a region in which the well is to be formed. Next, the manufacturing apparatus performs heat treatment for a laminate obtained by the ion implantation of Mg to the region in which the well is to be formed. The P type impurity such as Mg introduced into the GaN layer 110 is activated by the heat treatment, and the P type well region 21 is formed in the N type GaN layer 110. In addition, in the well region 21, defects caused by the ion implantation can be recovered to some extent by the heat treatment.

Next, as illustrated in FIG. 9C, the manufacturing apparatus performs ion implantation of Si as a N type impurity in the P type well region 111 to a region in which the N type source is to be formed. A part of the single-crystalline intermediate layer 40, which is located above the region in which the source is to be formed, is amorphized by the ion implantation to become an amorphous intermediate layer 41.

Next, the manufacturing apparatus performs heat treatment for a laminate obtained by the ion implantation of Si to the region in which the source is to be formed. The N type impurity such as Si introduced into the well region 111 is activated by the heat treatment, and the N⁺ type source region 31 is formed in the P⁻ type well region 111. In addition, in the source region 31, defects caused by the ion implantation can be recovered to some extent by the heat treatment.

Subsequent steps are the same as those in the second embodiment. The manufacturing apparatus forms the gate insulating film 50 (refer to FIG. 8), the gate electrode 60 (refer to FIG. 8), and the source electrode 70 (refer to FIG. 8) on the side of the surface 2a of the GaN substrate 2. In addition, the manufacturing apparatus forms the drain electrode 80 (refer to FIG. 8) on the side of the rear surface 2b of the GaN substrate 2. The GaN semiconductor device 1B illustrated in FIG. 8 is completed after the above steps.

As described above, the GaN semiconductor device 1B according to the third embodiment includes the vertical MOSFET 100B having the channel region in the well region 111. The vertical MOSFET 100B has the intermediate layer 40 arranged between the second GaN layer 30 and the gate insulating film 50. The intermediate layer 40 has a band gap smaller than that of the gate insulating film 50 and has a band offset with the second GaN layer 30. The intermediate layer 40 is arranged at a position opposed to the gate electrode 60 through the gate insulating film 50. The intermediate layer 40 has high resistance and inhibits ohmic contact, and thus, avoids the source contact region SC in which the source electrode 70 is in contact with the source region 31. Accordingly, the GaN semiconductor device 1B produces a similar effect to the GaN semiconductor device 1A according to the second embodiment.

When the electrical capacitance of the intermediate layer 40 is C2 and the band offset between the intermediate layer 40 and the second GaN layer 30 is ΔE2, the relation of 1.6×10⁻⁶/C2<ΔE2 is preferably satisfied also in the GaN semiconductor device 1B. Accordingly, electrons existing in the channel region of the vertical MOSFET 100B can be prevented from tunneling to the conduction band of the intermediate layer 40, and parallel conduction can be prevented. Accordingly, in the channel region, a decrease in electrons can be suppressed, and therefore, the mobility of electrons can be further improved.

The intermediate layer 40 preferably forms a heterojunction with the second GaN layer 30 also in the GaN semiconductor device 1B. The thickness of the intermediate layer 40 is preferably 0.25 nm or more and 7 nm or less, and more preferably 0.25 nm or more and 2 nm or less.

In addition, the threshold voltage of the vertical MOSFET 100B may be set to be 3.0 V or more. Accordingly, the vertical MOSFET 100B can be used as a power MOSFET.

### Fourth Embodiment

In the above second and third embodiments, the case where the transistor of the GaN semiconductor device according to the embodiment of the present invention is the vertical MOSFET having a planar structure has been described. However, the vertical MOSFET is not limited to the planar structure. The vertical MOSFET may have a trench gate structure.

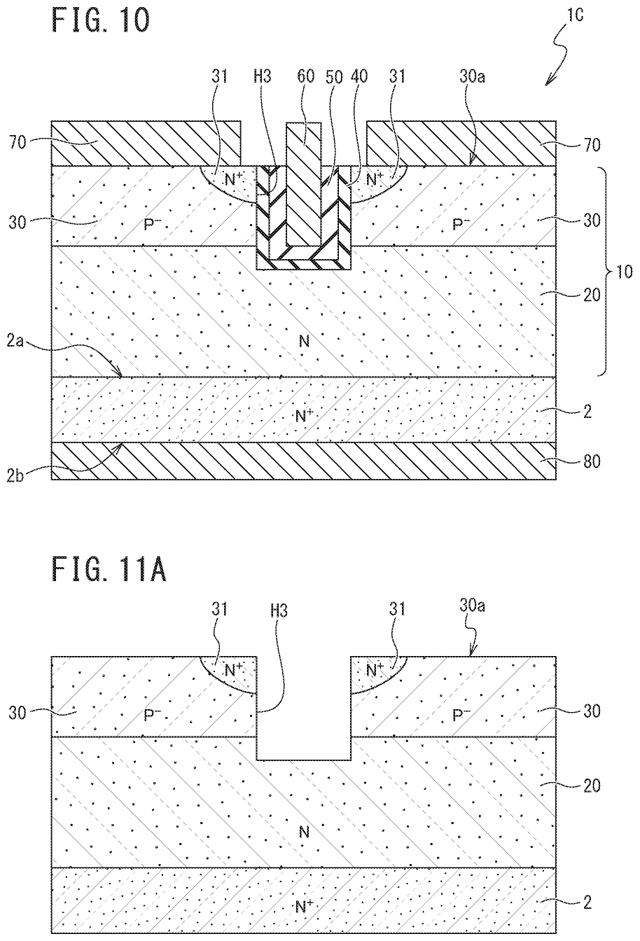

FIG. 10 is a cross-sectional view illustrating a configuration example of a GaN semiconductor device 1C according to a fourth embodiment of the present invention. As illustrated in FIG. 10, the GaN semiconductor device 1C includes the GaN layer 10 in which a trench H3 is provided, and a N type vertical MOSFET 100C having a channel region in the second GaN layer 30. The vertical MOSFET 100C is an example of the “transistor” of the present invention. The trench H3 opens on the side of the surface 30a of the second GaN layer 30. The depth of the trench H3 is larger than the thickness of the second GaN layer 30, and the bottom part of the trench H3 reaches the first GaN layer 20.

The intermediate layer 40, the gate insulating film 50, and the gate electrode 60 are arranged on the inside of the trench H3. The side surface and the bottom surface of the trench H3 are covered with the intermediate layer 40 and the gate insulating film 50 in this order. In addition, the gate electrode 60 is sandwiched by the gate insulating film 50 from both sides in the horizontal direction.

In the GaN semiconductor device 1C, a region of the second GaN layer 30, which is located between the first GaN layer 20 and the source region 31 and is opposed to the gate electrode 60 through the gate insulating film 50, becomes the channel region of the vertical MOSFET 100C. An on-state current of the vertical MOSFET 100C flows from the drain electrode 80 through the GaN substrate 2, the first GaN layer 20, the channel region, and the source region 31 to the source electrode 70. In addition, the source electrode 70 is in contact with not only the source region 31 but also the surface 30a of the second GaN layer 30. Accordingly, the electric potential of the second GaN layer 30 is fixed to the electric potential of the source electrode 70.

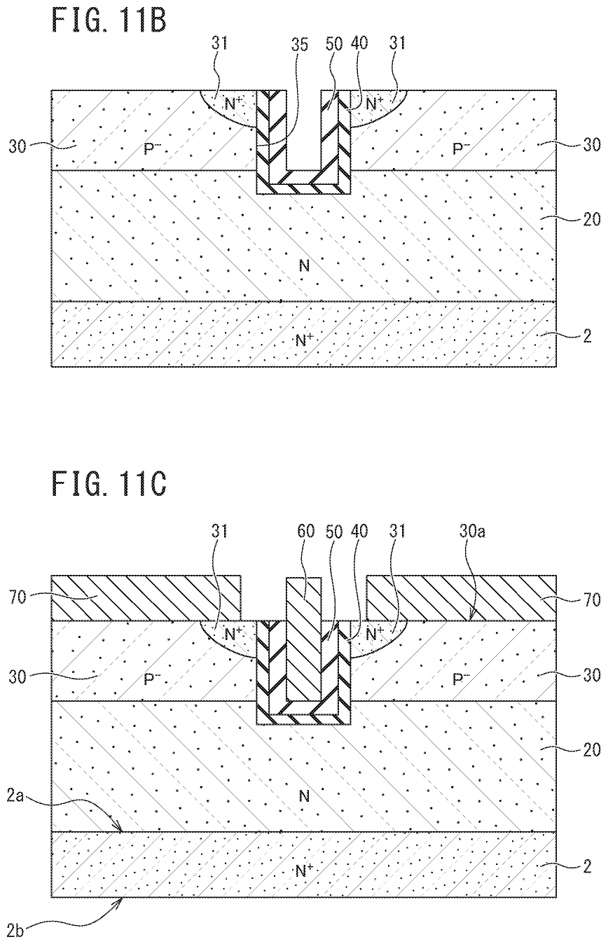

FIGS. 11A to 11C are cross-sectional views illustrating a manufacturing method of the GaN semiconductor device 1C according to the fourth embodiment of the present invention in the order of steps. The GaN semiconductor device 1C is manufactured by various manufacturing apparatuses such as a deposition apparatus, an exposure apparatus, and an etching apparatus. In FIG. 11A, the steps are the same as those in the second embodiment until the step of forming the P⁻ type second GaN layer 30. After forming the second GaN layer 30, the manufacturing apparatus performs ion implantation of Si as a N type impurity in the second GaN layer 30 to a region in which the source is to be formed.

Next, the manufacturing apparatus sequentially dry etches the second GaN layer 30 and the first GaN layer 20 from the side of the surface 30a of the second GaN layer 30 to form the trench H3. Next, the manufacturing apparatus performs heat treatment for a laminate in which the trench H3 is formed. The N type impurity such as Si introduced into the second GaN layer 30 is activated by the heat treatment, and the N⁺ type source region 31 is formed in the P⁻ type second GaN layer 30. In addition, in the source region 31, defects caused by the ion implantation can be recovered to some extent by the heat treatment. In addition, in the second GaN layer 30 and the first GaN layer 20, defects caused by the forming of the trench H3 can be recovered to some extent by the heat treatment.

Next, as illustrated in FIG. 11B, the manufacturing apparatus epitaxially grows the intermediate layer 40 on the second GaN layer 30. Next, the manufacturing apparatus forms the gate insulating film 50 on the intermediate layer 40 by a plasma CVD method. Next, the manufacturing apparatus partially wet etches the gate insulating film 50 and the intermediate layer 40. Accordingly, the manufacturing apparatus leaves the gate insulating film 50 and the intermediate layer 40 in the trench H3 and removes the gate insulating film 50 and the intermediate layer 40 from the other region.

Next, as illustrated in FIG. 11C, the manufacturing apparatus forms a metal film on the side of the surface 2a of the GaN substrate 2 and forms the gate electrode 60 and the source electrode 70 by patterning the formed metal film. The forming of the metal film is performed by vapor deposition, sputtering, or the like. The patterning of the metal film is performed by dry etching or liftoff.

In addition, before or after the forming step of the gate electrode 60 and the source electrode 70, the manufacturing apparatus forms a metal film on the side of the rear surface 2b of the GaN substrate 2 and forms the drain electrode 80 (refer to FIG. 10) by patterning the formed metal film if necessary. The forming of the metal film is performed by vapor deposition, sputtering, or the like. The patterning of the metal film is performed by dry etching or liftoff. The GaN semiconductor device 1C illustrated in FIG. 10 is completed after the above steps.

As described above, the GaN semiconductor device 1C according to the fourth embodiment includes the vertical MOSFET 100C having the channel region in the second GaN layer 30. The vertical MOSFET 100C has the intermediate layer 40 arranged between the second GaN layer 30 and the gate insulating film 50. The intermediate layer 40 has a band gap smaller than that of the gate insulating film 50 and has a band offset with the second GaN layer 30. The intermediate layer 40 is arranged at a position opposed to the gate electrode 60 through the gate insulating film 50. The intermediate layer 40 has high resistance and inhibits ohmic contact, and thus, avoids the source contact region SC in which the source electrode 70 is in contact with the source region 31. Accordingly, the GaN semiconductor device 1C produces a similar effect to the GaN semiconductor device 1A according to the second embodiment.

When the electrical capacitance of the intermediate layer 40 is C2 and the band offset between the intermediate layer 40 and the second GaN layer 30 is ΔE2, the relation of 1.6×10⁻⁶/C2<ΔE2 is preferably satisfied also in the GaN semiconductor device 1C. Accordingly, electrons existing in the channel region of the vertical MOSFET 100C can be prevented from tunneling to the conduction band of the intermediate layer 40, and parallel conduction can be prevented. Accordingly, in the channel region, a decrease in electrons can be suppressed, and therefore, the mobility of electrons can be further improved.

The intermediate layer 40 preferably forms a heterojunction with the second GaN layer 30 also in the GaN semiconductor device 1C. The thickness of the intermediate layer 40 is preferably 0.25 nm or more and 7 nm or less, and more preferably 0.25 nm or more and 2 nm or less.

In addition, the threshold voltage of the vertical MOSFET 100C may be set to be 3.0 V or more. Accordingly, the vertical MOSFET 100C can be used as a power MOSFET.

### OTHER EMBODIMENTS

As described above, the present invention has been described by the embodiments and the modified examples. However, it should not be understood that the description and the drawings which constitute a part of the present disclosure limit the present invention. From the present disclosure, various alternative embodiments and modified examples will be easily found by those skilled in the art.

For example, the “gate insulating film” of the present invention is not limited to the SiO₂ film, and a silicon oxynitride (SiON) film, a strontium oxide (SrO) film, and a silicon nitride (SiN) film can also be used. In addition, for the gate insulating film, a composite film in which multiple single-layered insulating films are laminated, or the like can also be used. A MOSFET using, as the gate insulating film, an insulating film other than a SiO₂ film may be referred to as a MISFET. The MISFET means a more comprehensive insulated gate transistor including a MOSFET.

As described above, it is certain that the present invention includes various embodiments and the like which are not described herein. At least one of various kinds of omission, replacement, and modification can be made for the components without departing from the scope of the above-described embodiments and modified examples. In addition, the effects described herein are merely exemplified and not limitative, and furthermore, other effects may be exerted. The technical scope of the present invention is defined solely by matters specifying the invention according to claims as deemed appropriate to the above description.

The present invention can also have the following structures.

(1) A nitride semiconductor device including: a gallium nitride-based semiconductor substrate having a first main surface and a second main surface located on the opposite side of the first main surface; a gallium nitride-based semiconductor layer provided on the side of the first main surface of the gallium nitride-based semiconductor substrate; and a transistor having a channel region in the gallium nitride-based semiconductor layer, in which the transistor includes: a gate insulating film provided above the gallium nitride-based semiconductor layer; an intermediate layer arranged between the gallium nitride-based semiconductor layer and the gate insulating film, having a band gap smaller than that of the gate insulating film, and having a band offset with the gallium nitride-based semiconductor layer; agate electrode provided on the gate insulating film; a first conductivity type source region provided in the gallium nitride-based semiconductor layer; and a source electrode provided on the gallium nitride-based semiconductor layer and being in contact with the source region, and the intermediate layer is arranged at a position opposed to the gate electrode through the gate insulating film and avoids a source contact region in which the source electrode is in contact with the source region.

(2) The nitride semiconductor device according to (1), in which, when an electrical capacitance of the intermediate layer is C2 and the band offset between the intermediate layer and the gallium nitride-based semiconductor layer is ΔE2, a relation of 1.6×10⁻⁶/C2<ΔE2 is satisfied.

(3) The nitride semiconductor device according to (1) or (2), in which the first conductivity type is a N type, and a threshold voltage of the transistor is 3.0 V or more.

(4) The nitride semiconductor device according to any one of (1) to (3), in which the gallium nitride-based semiconductor layer is composed of gallium nitride.

(5) The nitride semiconductor device according to any one of (1) to (3), in which the gallium nitride-based semiconductor layer includes a first conductivity type first gallium nitride layer and a second conductivity type second gallium nitride layer provided on the first gallium nitride layer, and the source region is provided in the second gallium nitride layer.

(6) The nitride semiconductor device according to any one of (1) to (5), in which the gate insulating film is composed of silicon oxide or aluminum oxide.

(7) The nitride semiconductor device according to any one of (1), (2), and (4) to (6), in which the intermediate layer is an aluminum nitride-based semiconductor layer.

(8) The nitride semiconductor device according to any one of (1) to (7), in which the intermediate layer forms a heterojunction with the gallium nitride-based semiconductor layer.

(9) The nitride semiconductor device according to any one of (1) to (8), in which the transistor further includes a first conductivity type drain region provided in the gallium nitride-based semiconductor layer, and a drain electrode provided on the gallium nitride-based semiconductor layer and being in contact with the drain region, and the intermediate layer avoids a drain contact region in which the drain electrode is in contact with the drain region.

(10) The nitride semiconductor device according to any one of (1) to (8), further including: a drain electrode provided on the side of the second main surface of the gallium nitride-based semiconductor substrate.

(11) The nitride semiconductor device according to any one of (1) to (10), in which a thickness of the intermediate layer is 0.25 nm or more and 7 nm or less.

(12) The nitride semiconductor device according to any one of (1) to (10), in which a thickness of the intermediate layer is 0.25 nm or more and 2 nm or less.

### REFERENCE SIGNS LIST

1, 1A, 1B, 1C GaN semiconductor device
2 GaN substrate
2a, 30a surface
2b rear surface
10 GaN layer
20 first GaN layer
30 second GaN layer
21 well region
31 source region
32 drain region
33 impurity region
40, 41 intermediate layer
50 gate insulating film
60 gate electrode
65 insulating film
70 source electrode
80 drain electrode
100 lateral MOSFET
100A, 100B, 100C vertical MOSFET
110 GaN layer
111 well region
111a surface
DC drain contact region
H1 first contact hole
H2 second contact hole
H3 trench
SC source contact region

1. A nitride semiconductor device comprising:
a gallium nitride-based semiconductor substrate having a first main surface and a second main surface located on the opposite side of the first main surface;
a gallium nitride-based semiconductor layer provided on the side of the first main surface of the gallium nitride-based semiconductor substrate; and
a transistor having a channel region in the gallium nitride-based semiconductor layer, wherein
the transistor includes:
a gate insulating film provided above the gallium nitride-based semiconductor layer;
an intermediate layer arranged between the gallium nitride-based semiconductor layer and the gate insulating film, having a band gap smaller than the band gap of the gate insulating film, and having a band offset with the gallium nitride-based semiconductor layer;
a gate electrode provided on the gate insulating film;
a first conductivity type source region provided in the gallium nitride-based semiconductor layer; and
a source electrode provided on the gallium nitride-based semiconductor layer and being in contact with the source region, and
the intermediate layer is arranged at a position opposed to the gate electrode through the gate insulating film and configured to avoid a source contact region in which the source electrode is in contact with the source region.

2. The nitride semiconductor device according to claim 1, wherein,
when an electrical capacitance of the intermediate layer is C2 and the band offset between the intermediate layer and the gallium nitride-based semiconductor layer is ΔE2, a relation of 1.6×10⁻⁶/C2 [F/cm²]<ΔE2[V] is satisfied.

3. The nitride semiconductor device according to claim 1, wherein
the first conductivity type is a N type, and
a threshold voltage of the transistor is 3.0 V or more.

4. The nitride semiconductor device according to claim 1, wherein
the gallium nitride-based semiconductor layer is composed of gallium nitride.

5. The nitride semiconductor device according to claim 1, wherein
the gallium nitride-based semiconductor layer includes a first conductivity type first gallium nitride layer and a second conductivity type second gallium nitride layer provided on the first gallium nitride layer, and
the source region is provided in the second gallium nitride layer.

6. The nitride semiconductor device according to claim 1, wherein
the gate insulating film is composed of silicon oxide or aluminum oxide.

7. The nitride semiconductor device according to claim 1, wherein
the intermediate layer is an aluminum nitride-based semiconductor layer.

8. The nitride semiconductor device according to claim 1, wherein
the intermediate layer forms a heterojunction with the gallium nitride-based semiconductor layer.

9. The nitride semiconductor device according to claim 1, wherein
the transistor further includes a first conductivity type drain region provided in the gallium nitride-based semiconductor layer, and a drain electrode provided on the gallium nitride-based semiconductor layer and being in contact with the drain region, and
the intermediate layer is configured to avoid a drain contact region in which the drain electrode is in contact with the drain region.

10. The nitride semiconductor device according to claim 1, further comprising:
a drain electrode provided on the side of the second main surface of the gallium nitride-based semiconductor substrate.

11. The nitride semiconductor device according to claim 1, wherein
a thickness of the intermediate layer is 0.25 nm or more and 7 nm or less.

12. The nitride semiconductor device according to claim 1, wherein
a thickness of the intermediate layer is 0.25 nm or more and 2 nm or less.
